(19) United States
(12) Patent Application Publication
(10) Pub. No.: US 2005/0221513 A1
(43) Pub. Date: Oct. 6, 2005

(54) Method of controlling trimming of a gate electrode structure

(75) Inventors: Hongyu Yue, Austin, TX (US); Lee Chen, Cedar Creek, TX (US)

Correspondence Address: PILLSBURY WINTHROP SHAW PITTMAN, LLP, P.O. BOX 10500, MCLEAN, VA, 22102, US

(73) Assignee: Tokyo Electron Limited, Tokyo (JP)

(21) Appl. No.: 10/812,952

(22) Filed: Mar. 31, 2004

(51) Int. Cl. H01L 21/66; H01L 21/4763; H01L 21/3205; G01R 31/26

(52) U.S. Cl. 438/14

(57) ABSTRACT

A method and processing tool are provided for controlling trimming of a gate electrode structure containing a gate electrode layer with a first dimension by determining the first dimension of the gate electrode structure, choosing a target trimmed dimension, feeding forward the first dimension and the target trimmed dimension to a process model to create a set of process parameters, performing a trimming process on the gate electrode structure, including controlling the set of process parameter, trimming the gate electrode structure, and measuring a trimmed dimension of the gate electrode structure. The trimming process may be repeated at least once until the target trimmed dimension is obtained, where the trimmed dimension may be fed backward to the process model to create a new set of process parameters.

### CROSS REFERENCE TO RELATED APPLICATIONS

The present invention is related to U.S. patent application Ser. No. 10/756,759, filed Jan. 4, 2004, Attorney Docket No. 071469-0307410, the entire contents of which are herein incorporated by reference.

### FIELD OF THE INVENTION

The present invention relates to semiconductor manufacturing, particularly to a method of controlling trimming of a gate electrode structure in a chemical trimming process.

### BACKGROUND OF THE INVENTION

Plasma processing systems are used in the manufacture and processing of semiconductors, integrated circuits, displays, and other devices or materials. Plasma processing can be used to transfer a pattern of an integrated circuit from a lithographic mask to a semiconductor substrate. The lithographic mask can comprise an etch-resistant photoresist layer that is deposited over a substrate, exposed to a selected lithographic pattern and developed. In addition to the photoresist layer, the lithographic mask structure can include additional mask layers, e.g., anti-reflective coatings (ARCs). ARC layers are frequently used to reduce light reflections from the substrate during lithography steps, and sacrificial masks can be used to pattern areas on a substrate. The substrate is then anisotropically etched in a plasma process where the patterned photoresist/mask layers define openings in the substrate.

The minimum feature sizes of microelectronic devices are approaching the deep sub-micron regime to meet the demand for faster, lower power microprocessors and digital circuits. A critical dimension (CD) of a circuit is the width of a line or space that has been identified as critical to the device being fabricated to operate properly and it further determines the device performance.

The minimum initial feature size that can be achieved using a layer of photoresist material is limited by the lithographic techniques used to expose and pattern the photoresist layer. Commonly, a dimension of a patterned photoresist (PR) layer is trimmed beyond the limits of the lithographic technique utilizing plasma etching methods. The reduction in CD during the plasma etching process is referred to as CD-bias. However, a consequence of plasma PR-trim process is iso-dense CD-bias, which is the difference between the CDs of dense (closely spaced) and isolated structures, while keeping all other processing parameters (e.g., focus and exposure) constant. This is due to the nature of the neutral-dominant isotropic etching process.

### SUMMARY OF THE INVENTION

The present invention provides a method of trimming a gate electrode structure by determining a first dimension of the gate electrode structure, choosing a target trimmed dimension, feeding forward the first dimension and the target trimmed dimension to a process model to create a set of process parameters, and performing a trimming process on the gate electrode structure, including controlling the set of process parameters in the trimming process, and trimming the gate electrode structure.

The trimming process may be repeated at least once until the target trimmed dimension is obtained, where the trimmed dimension may be fed backward to the process model to create a new set of process parameters.

A processing tool is provided for trimming a gate electrode structure. The processing tool contains a substrate loading chamber configured for loading and unloading a substrate with a gate electrode structure having a first dimension, a transfer system configured for transferring the substrate within the processing tool, at least one processing system configured for performing a trimming process on the gate electrode structure to form a trimmed dimension, at least one controller configured for storing a process model capable of creating a set of process parameters from the first dimension and a target trimmed dimension, and controlling the set of process parameters in the trimming process, and a further processing system for measuring at least one of the first dimension and the trimmed dimension of the gate electrode structure.

### BRIEF DESCRIPTION OF THE DRAWINGS

In the drawings:

FIGS. 1A-1G show a schematic cross-sectional representation of a process flow for trimming a gate electrode structure according to an embodiment of the invention;

FIG. 2 schematically shows reaction layer thickness as a function of reactant gas exposure according to an embodiment of the invention;

FIGS. 3A-3C show a schematic cross-sectional representation of a process flow for trimming gate electrode structure according to another embodiment of the invention;

FIGS. 4A-4B show a schematic cross-sectional representation of a process flow for trimming a gate electrode structure according to yet another embodiment of the invention;

FIGS. 5A-5D show a schematic cross-sectional representation of a process flow for trimming a gate electrode structure according to still another embodiment of the invention;

FIG. 6 is a flowchart for trimming a gate electrode structure according to an embodiment of the invention;

FIG. 7 is a flowchart for controlling trimming of a gate electrode structure according to an embodiment of the invention;

FIG. 8 schematically shows a processing tool for trimming a gate electrode structure according to an embodiment of the invention; and

FIG. 9 is a depiction of a general purpose computer which may be used to implement the present invention.

### DETAILED DESCRIPTION OF SEVERAL EMBODIMENTS

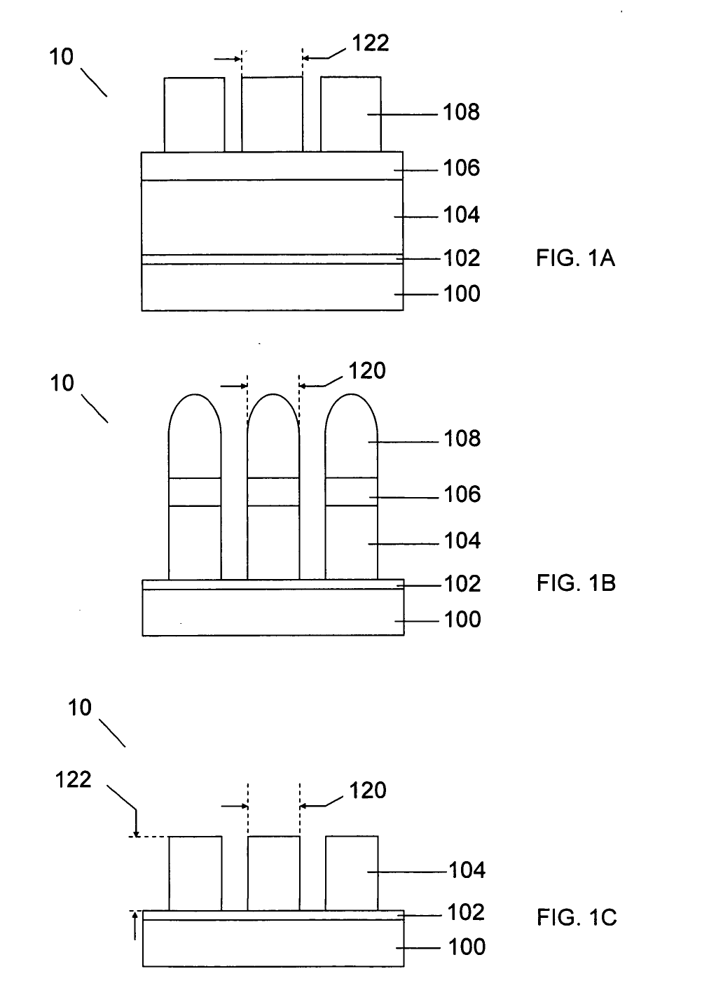

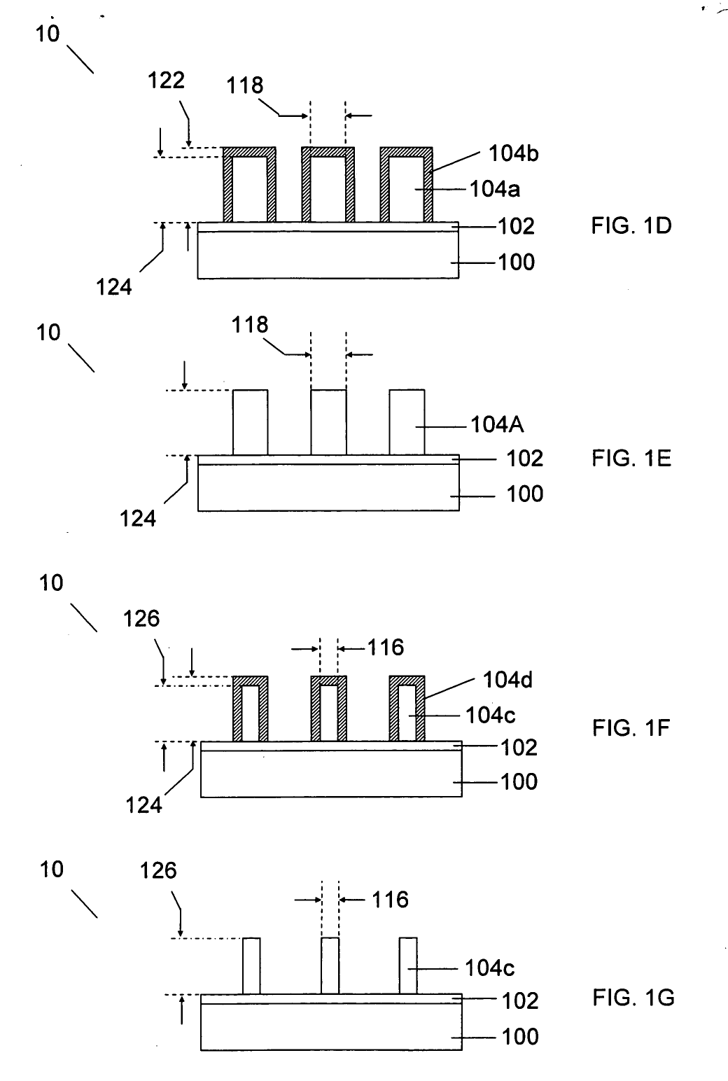

FIGS. 1A-1G show a schematic cross-sectional representation of a process flow for trimming a gate electrode structure according to an embodiment of the invention. Utilizing a soft-mask processing scheme, a dimension of a lithographically patterned gate electrode structure is trimmed by a chemical etching process. The dimension after trimming can be below the lithographic dimension of the photoresist pattern, or it can be any dimension.

FIG. 1A shows a gate electrode structure 10 containing a substrate 100, a high-k layer 102, a gate electrode layer 104, an organic ARC layer 106, and a patterned photoresist layer 108. The gate electrode layer 104 can be a Si-containing layer, e.g., amorphous Si, poly-Si, or SiGe or any combination thereof. Alternately, the gate electrode layer 104 can be a metal-containing layer, for example a metal (e.g., Ru), a metal alloy (e.g., TiNi), a metal nitride (e.g., TaN, TaSiN, TiN, HfN), or a metal oxide (e.g., RuO₂) or any combination thereof. The high-k layer 102 can, for example, contain HfO₂, HfSiOx, ZrO₂, or ZrSiOx or a combination of two or more thereof. The patterned photoresist layer 108 can be formed by exposing a photoresist layer to light through a mask, and then removing the unexposed areas with a developer solution. The resulting patterned photoresist layer 108 in FIG. 1A, with an initial lithographic dimension 122, can be used to transfer the lithographic pattern to the underlying layers 104 and 106 using an anisotropic etch process such as Reactive Ion Etching (RIE). The etching of the gate electrode layer 104 and the organic ARC layer 106 can be carried out using wide variety of well-known etch gases. The etch gases can, for example, contain Cl₂, HBr, HCl, CF₄, SF₆, C₂F₆, or NF₃ or any combination of two or more thereof. The gate electrode structure 10, shown in FIG. 1A, can require an etch process of about 4 min to form the gate electrode structure 10 shown in FIG. 1B. The etch process creates a small CD-bias corresponding to the difference between the initial lithographic dimension 122 and the first horizontal dimension 120 in the photoresist layer 108, the organic ARC layer 106, and the gate electrode layer 104, as shown in FIG. 1B.

Next, the photoresist layer 108 and the organic ARC layer 106 can be removed before the chemical trimming process is carried out, as shown in FIG. 1C, or alternately, the photoresist layer 108 and the organic ARC layer 106 can be used to protect the horizontal (top) surface of the gate electrode layer 104 during the trimming process. In FIG. 1C, the gate electrode layer 104 is characterized by the first horizontal dimension 120 and a first vertical dimension 122. A chemical trimming process can further reduce the CD (first horizontal dimension 118, see FIG. 1D) below the lithographical dimension 120, without changing the iso-dense CD-bias or the profile (maybe a little change on profile) of the gate electrode layer 104.

In the chemical trimming process, the gate electrode structure 10 in FIG. 1C can be exposed to a reactant gas that reacts isotropically with the gate electrode structure 10 to form the reaction layer 104b shown in FIG. 1D. The reactant gas can be exposed to the gate electrode structure in a thermal process or in a plasma process. The thickness of the reaction layer 104b depends on the process conditions, e.g., the type of reactant gas, reactant gas pressure, exposure time, and substrate temperature. Formation of the reaction layer 104b hinders further reaction between the remaining gate electrode layer 104a and the reactant gas by acting as a physical diffusion barrier. The gate electrode structure 10 is exposed to the reactant gas for a time period that enables formation of a reaction layer 104b with a desired thickness.

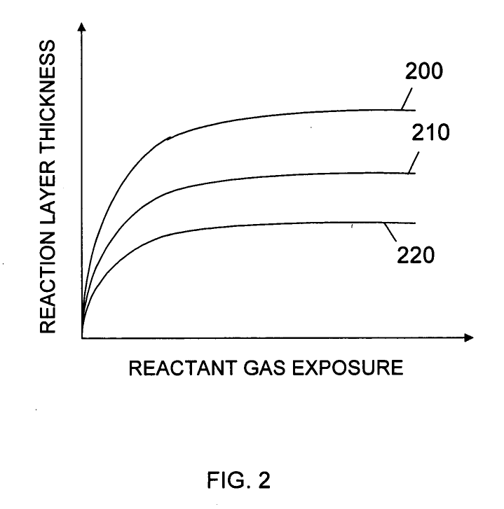

FIG. 2 schematically shows reaction layer thickness as a function of reactant gas exposure time according to an embodiment of the invention. Curves 200-220 show different reaction layer thicknesses for different processing conditions. As seen in FIG. 2, a rapid increase in reaction layer thickness can be initially observed, followed by a “flattening out” of the rate of increase with increasing exposure time. The “flattening out” is due to a self-limiting reaction, where the thickness of the reaction layer approaches an asymptotic value. In practice, process conditions are selected that form a reaction layer with the required control and repeatability, on a timescale that is practical for semiconductor manufacturing. Different trimming recipes can thus be developed that yield different reaction layer thicknesses and allow good repeatable control over the trimming process.

For a poly-Si gate electrode layer 104, a SiO₂ reaction layer 104b with a thickness between about 2 nm to about 5 nm can be formed on a time scale that is practical for manufacturing semiconductor devices, e.g., between about 10 and about 30 sec, depending on the plasma processing conditions and the substrate temperature. In one embodiment of the invention, a reactant gas containing excited oxygen species is used to react with a poly-Si gate electrode layer to form a SiO₂ reaction layer 104b. The excited oxygen species can be produced using an O₂ plasma source. The O₂ plasma source can be a remote plasma source if the source needs to be removed from the substrate in the processing system.

In another embodiment of the invention, an oxygen-containing gas such as O₂ or H₂O, may be used to thermally oxidize a poly-Si gate electrode to form a SiO₂ reaction layer. In yet another embodiment of the invention, a wet oxidation process may be used. The oxidizing process may, for example, immerse the substrate in warm H₂O or an acidic solution.

In one example, the O₂ plasma processing conditions and the substrate temperature were selected to yield about a 4 nm thick SiO₂ reaction layer 104b in about 15 sec, on both isolated and dense gate electrode structures. The thickness of the SiO₂ reaction layer 104 appeared to be saturated at room temperature after about 15 sec, and longer exposure times did not result in increased thickness of the reaction layer 104b. The short processing times for forming a SiO₂ reaction layer 104b allows for the required high substrate through-put.

Referring back to FIG. 1D, when a reaction layer 104b with a desired thickness has been formed, the exposure of the gate electrode structure 10 to the reactant gas is stopped. Thereafter, the reaction layer 104b is removed (stripped) from the unreacted gate electrode layer 104a. The reaction layer 104b can, for example, be removed by exposing the gate electrode structure 10 to an etch gas. Choosing an etch gas that is capable of removing the reaction layer 104b can depend on the gate electrode material. Removal of the reaction layer 104b is selective to unreacted gate electrode material and results in a trimmed gate electrode layer 104a shown in FIG. 1E. The etch gas can, for example be aqueous HF vapor (HF_{(aq)}). As those skilled in the art will appreciate, HF_{(aq)} has high etch selectivity for SiO₂ over Si, allowing fast, selective removal of the SiO₂ reaction layer 104b from the remaining Si gate electrode layer 104a. The exposure of the SiO₂ reaction layer 104b to the HF_{(aq)} etch gas can be carried out for a predetermined time period that is sufficiently long to complete the removal of the SiO₂ reaction layer 104b. In one example of the invention, a 4 nm thick SiO₂ reaction layer 104b can be removed in about 10 sec. The trimmed gate electrode layer 104a is characterized by a second horizontal dimension 118 and a second vertical dimension 124 that are smaller than the first horizontal dimension 120 and the first vertical dimension 122 in FIG. 1C, respectively. The trimming process can be repeated if it is desired to further trim the gate electrode layer 104a. Repeating the trimming process forms a reaction layer 104d in FIG. 1F, and a trimmed gate electrode layer 104c with new dimensions 116 and 126 in FIG. 1G. Another example to trim away oxidized film 104a is to use COR (chemical oxide removal). Etch gases HF and NH₃ are used to react with the oxide film and then heat treatment is used to evaporate the trimmed product. Another COR example is to use NF₃ and NH₃ etch gases excited by a remote plasma source. Still another COR example is to use NH₄F vapor to thermally react with the oxide film. Another example to trim away oxidized film 104a is to use a wet process. The wet process may, for example, immerse the substrate in a buffered HF solution.

A trimming cycle includes forming a reaction layer and removing the reaction layer. In FIG. 1C-1E, a trimming cycle reduces the first horizontal dimension 120 of the gate electrode layer 104 twice as much as the first vertical dimension 122. In one embodiment of the invention, one trimming cycle can reduce the horizontal dimension 120 of a Si gate electrode layer 104 by about 8 nm and vertical dimension by about 4 nm. In one example, the first vertical dimension 120 can be about 120 nm and the first vertical dimension 122 can be about 140 nm. A trimming process containing 10 trimming cycles can reduce the first horizontal dimension 120 to about 40 nm and the first vertical dimension 122 to about 100 nm.

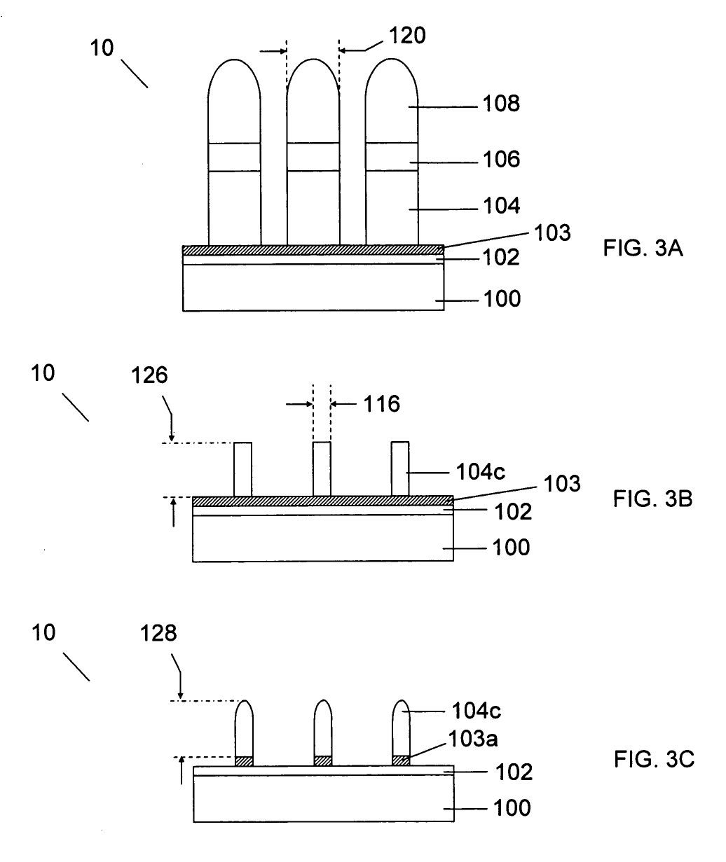

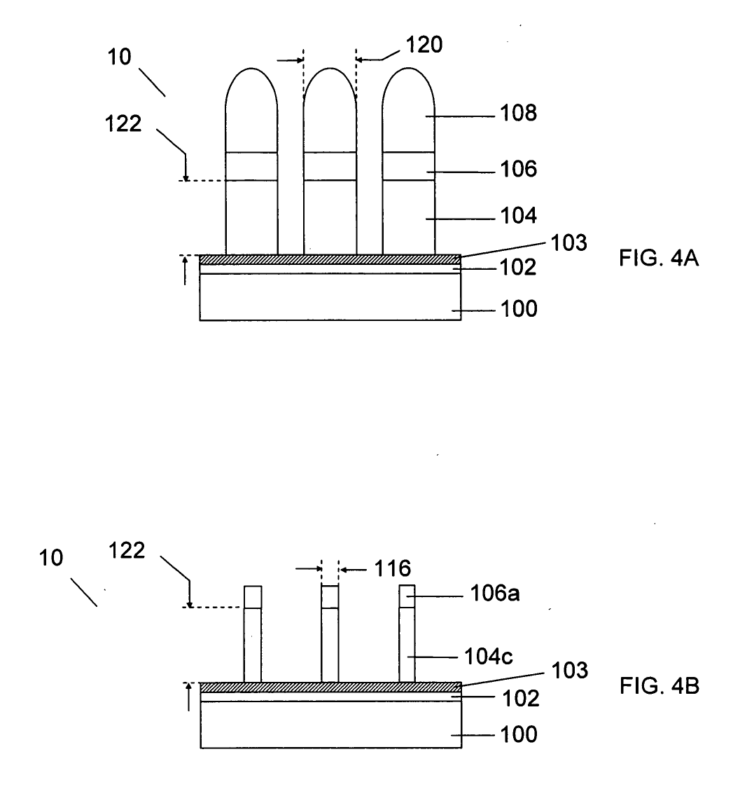

FIGS. 3A-3C show a schematic cross-sectional representation of a process flow for trimming a gate electrode structure according to another embodiment of the invention. In FIG. 3A, a metal-containing layer 103 is inserted between gate electrode layer 104 and the dielectric layer 102. The metal-containing layer 103 can, for example, be selected from TaN, TiN, TaSiN, Ru, or RuO₂ materials or any combinations thereof. The high-k layer 102 can, for example, contain HfO₂, HfSiOₓ, ZrO₂, or ZrSiOₓ or any combination of two or more thereof. Trimming of the gate electrode layer 104 can be carried out as described above in FIGS. 1B-1G, to form a gate electrode structure 10 with dimensions 116 and 126, as shown in FIG. 3B. Next, the trimmed gate electrode layer 104c can be used as a mask layer in an anisotropic etch process to define sub-lithographic etch features in the metal-containing layer 103, as shown in FIG. 3C. Etching of the metal-containing layer 103 reduces the dimension 126 of the gate electrode layer 104c according to the etch ratio of these layers. In the example of a poly-Si layer 104c and a TiN layer 103, the etch ratio can be about 1.5 (poly-Si/TiN). Therefore, in order to get the desired vertical dimension 128, the dimension 126 can be selected based on the etch ratio of layers 104 and 103. TaN, TiN, and TaSiN materials can be plasma etched using halogen-based gases, for example Cl₂. A Ru-containing material can, for example, be plasma etched using O₂ and Cl₂ gas mixture. Alternatively, as shown in FIG. 4A-4B, an inorganic ARC layer can be used to prevent reducing the dimension 126 while etching the metal containing layer 103.

FIGS. 4A-4B show a schematic cross-sectional representation of a process flow for trimming a gate electrode structure according to yet another embodiment of the invention. The gate electrode structure 10 in FIG. 4A contains an inorganic ARC layer 106 that is trimmed along with the gate electrode layer 104 to form a trimmed gate electrode structure 10 in FIG. 4B. The inorganic ARC layer 106 can, for example, contain SiN, and the dielectric layer 102 can be selected from SiO₂, SiOₓN_{y}, or high-k materials such as HfO₂, HfSiOₓ, ZrO₂, or ZrSiOₓ.

Trimming of a SiN ARC layer 106 and a poly-Si gate electrode layer 104 can be performed by exposing the gate electrode structure 10 to excited oxygen species in an O₂ plasma. The growth rate of a reaction layer can vary on the SiN ARC layer and the poly-Si gate electrode layer, but the asymptotic reaction layer thickness is expected be similar on the SiN and poly-Si materials.

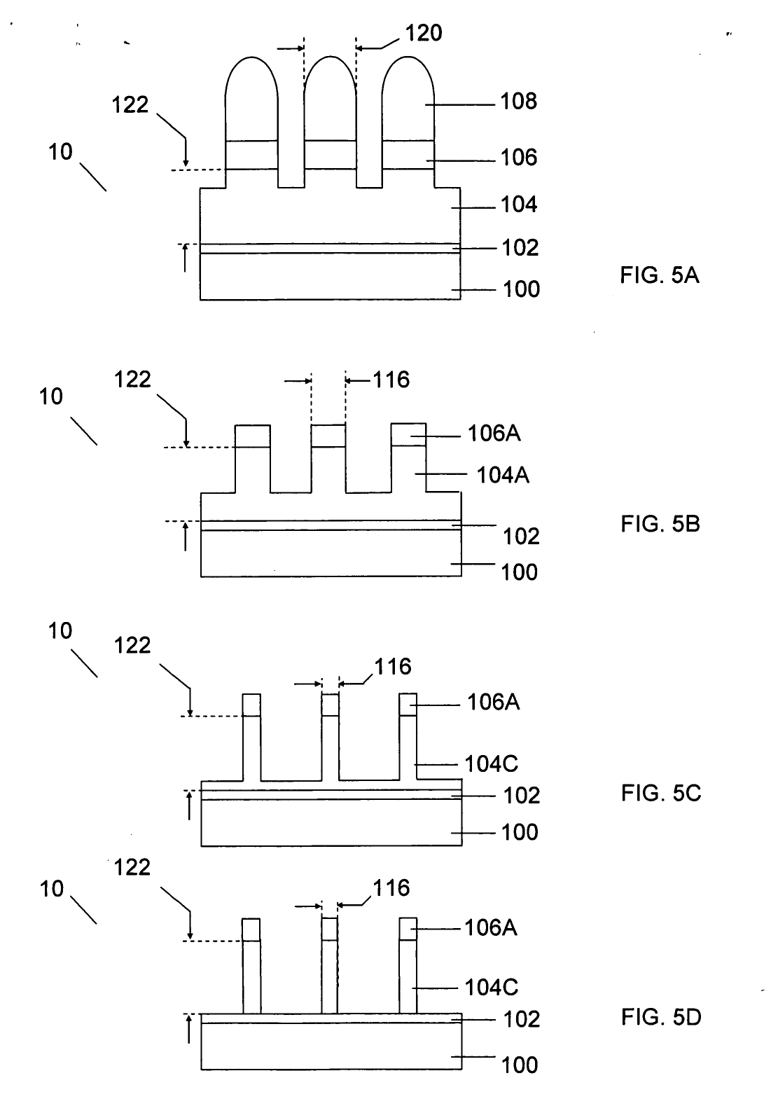

FIGS. 5A-5D show a schematic cross-sectional representation of a process flow for trimming a gate electrode structure according to still another embodiment of the invention. The gate electrode structure 10 contains a substrate 100, a dielectric layer 102, a gate electrode layer 104, an inorganic ARC layer 106, and a patterned photoresist layer 108. The inorganic ARC layer 106 can, for example, contain SiN, and the dielectric layer 102 can be selected from SiO₂, SiOxNy, and high-k materials such as HfO₂, HfSiOₓ, ZrO₂, and ZrSiOₓ. FIG. 5A shows a gate electrode structure following plasma etching of the inorganic ARC layer 106 and partial etching of the gate electrode layer 104. FIG. 5B shows the trimmed gate electrode structure 10 after one trimming cycle and FIG. 5C shows the trimmed gate electrode structure 10 after two trimming cycles. FIG. 5D shows the gate electrode structure 10 following anisotropic etching of the gate electrode layer 104c.

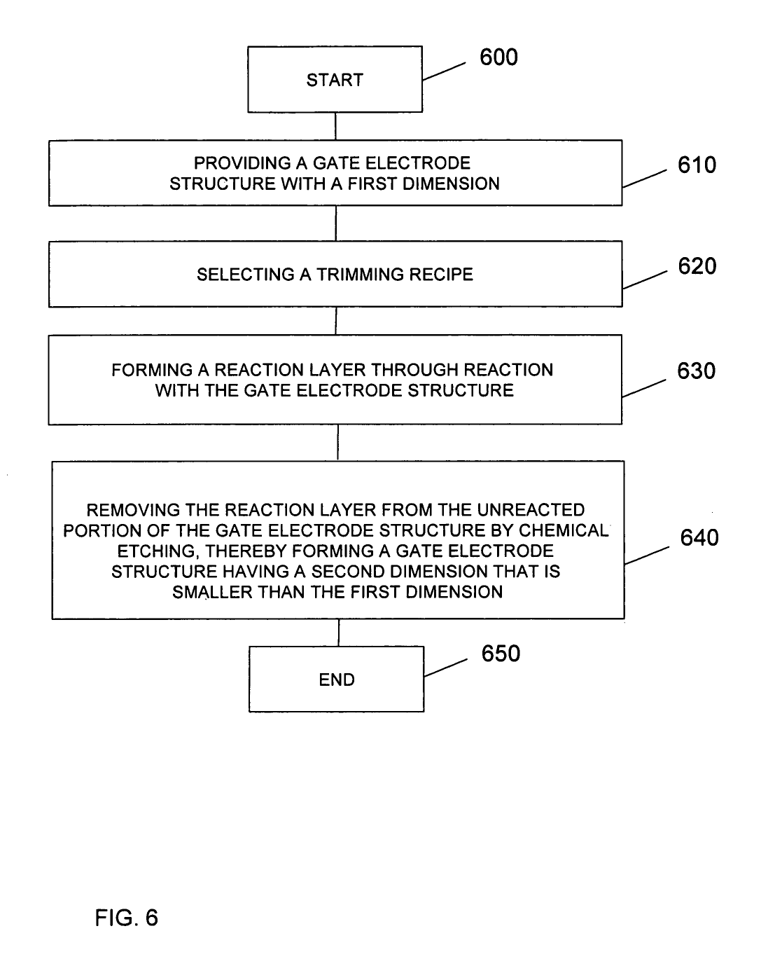

FIG. 6 is a flow-chart for trimming a gate electrode structure according to an embodiment of the invention. At 600, the process is started. At 610, a gate electrode structure containing a gate electrode layer with a first dimension is provided in a processing system. At 620, a trimming recipe is selected. A trimming recipe is selected that enables the desired trimming of the gate electrode structure. At 630, a reaction layer is formed through reaction with the gate electrode structure. In one embodiment of the invention, the reaction layer can be formed by exposing the gate electrode structure a reactant gas in a thermal process or in a plasma process. At 640, the reaction layer is removed from the unreacted portion of the gate electrode structure, thereby forming a gate electrode structure having a second dimension that is smaller than the first dimension. In one embodiment of the invention, the reaction layer can be removed by exposed it to an etch gas capable of selectively etching the reaction layer.

In one embodiment of the invention, a method is provided for controlling trimming of a gate electrode structure using a process model. The process model contains a set of process parameters that are used by a processing system to trim a dimension of the gate electrode structure in a trimming process. The process model can utilize a mathematical function to characterize the relationship between the process parameters and the reaction layer thickness. In one example, the abovementioned relationship may be expressed as shown in equation (1):
t=f(x)+b (1)
where t is the reaction layer thickness, b is a constant, and x is a set of process parameters used by the processing system to carry out the trimming process. The function f(x) can, for example, be a linear function or a quadratic function. The set of process parameters can, for example, include process gas pressure, substrate temperature, plasma power, and process time. The relationship between the process parameters and the reaction layer thickness in equation (1) is called a trim curve.

In one embodiment of the invention, a trim curve can be chosen that contains a single variable process parameter and other process parameters are kept constant. By selecting a single variable process parameter, for example process gas pressure, the target reaction layer thickness can be expressed as shown in equation (2):
t=g(p)+c (2)
where p is process gas pressure and c is a constant. This relationship between process gas pressure and the reaction layer thickness is called a trim curve based on pressure.

Alternately, a cluster of pressure trim curves can be obtained by varying at least one additional process parameter, e.g., plasma power. A cluster of available pressure trim curves can provide more process flexibility and reduce constraints on process operating conditions such as pressure control limit, power limit, gas flow controller resolution.

A process model containing a group of trim curves can be created by performing multiple trimming processes and correlating the different process parameters with the resulting reaction layer thickness and trim amount. The process model may then be used to control the set of process parameter according to the target reaction layer thickness, as shown in equation (3):
x=f⁻¹(t−b) (3)
where f⁻¹ is the inverse function of f.

In one embodiment of the invention, the first dimension of the gate electrode structure can be an initial critical dimension CD₀ (e.g., dimension 120 in FIG. 1C) and the target trimmed dimension can be a target critical dimension CDₜ (e.g., dimension 118 in FIG. 1E or dimension 116 in FIG. 1G). The dimensions CD₀ and CDₜ are then fed forward to a controller configured for calculating a target reaction layer thickness according to equation (4):
t=(CD₀−CDₜ)/2 (4)

In the example of using process gas pressure p as the single variable process parameter, a substrate having an initial dimension CD₀ and a target trimmed dimension CDₜ, the process gas pressure p required to obtain the target trimmed dimension CDₜ can be calculated from equation (5):
p=g⁻¹((CD₀−CDₜ)/2−c) (5)

Obviously, if the target reaction layer thickness is greater than the reaction layer thickness by an amount greater than what can be achieved in a single trimming process, it may be necessary to perform multiple trimming processes. The multiple trimming processes may be selected to yield the same reaction layer thickness or, alternatively, they may be selected to yield different reaction layer thicknesses.

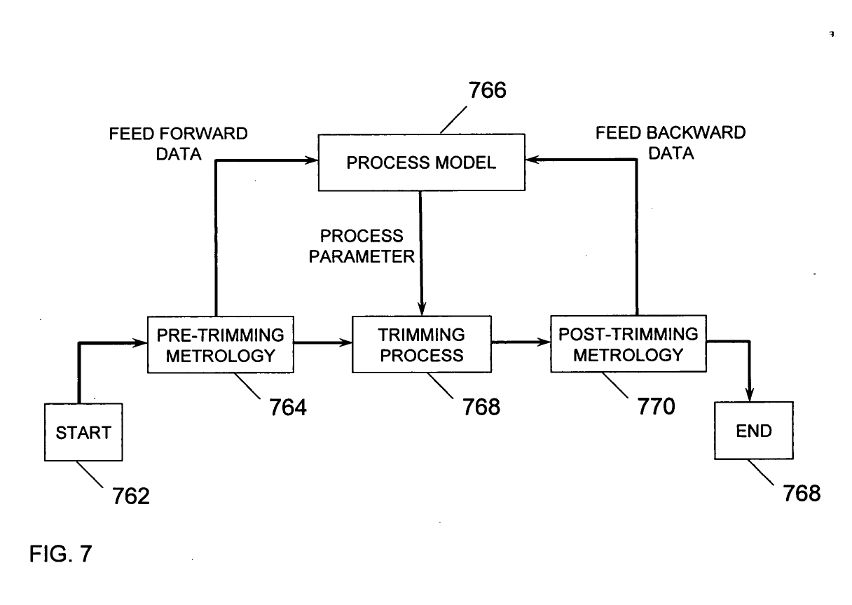

FIG. 7 is a flowchart for controlling trimming of a gate electrode structure according to an embodiment of the invention. At 762, the process is started. At 764, a first dimension of the gate electrode structure is measured in a pre-trimming metrology step. The first dimension and a target trimmed dimension are fed forward to a process model 766 to create a set of process parameters according to the first dimension and the target trimmed dimension. Subsequently, a trimming process is performed at 768 according to the process model to form a trimmed gate electrode structure having a trimmed dimension that is smaller than the first dimension. Following the trimming process, the trimmed dimension is measured in a post-trimming metrology step at 770.

If trimming process 768 yields a trimmed dimension that is greater that the desired target trimmed dimension, the trimming process 768 may be repeated at least once until the target trimmed dimension is obtained. The repeating may further include feeding backward the trimmed dimension to the process model 766 to create a new set of process parameters. Thus, the trimming process may be carried out multiple times until the target trimmed dimension is obtained, where a new set of process parameters may be created before each trimming process is performed. When the target trimmed dimension is obtained, the process ends at 768.

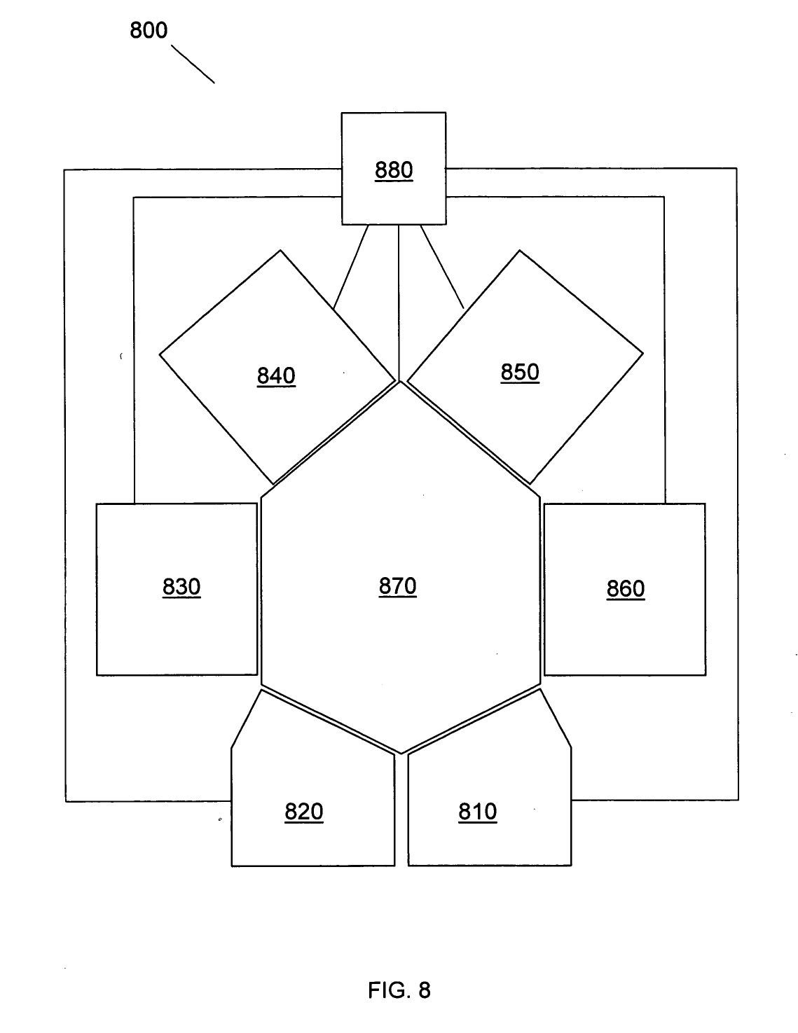

FIG. 8 schematically shows a processing tool for trimming a gate electrode structure according to an embodiment of the invention. The processing tool 800 can, for example, be a UnityMe etch tool from Tokyo Electron Limited, Akasaka, Japan. The processing tool 800 contains substrate loading chambers 810 and 820, processing systems 830-860, robotic transfer system 870, and controller 880. In one embodiment of the invention, plasma etching of a photoresist layer 108, an ARC layer 106, a gate electrode layer 104 (e.g., see FIG. 1), and a metal-containing layer 103 (e.g., see FIG. 3), can be performed in the processing system 840. In one embodiment of the invention, formation of a reaction layer through exposure of a gate electrode structure to a reactant gas can be performed in processing system 850, and the removal of the reaction layer 104b through exposure to an etch gas can be performed in processing system 860.

The formation and removal of the reaction layer 104b can be carried out in a single processing system as described above or, alternately, in different processing systems. The use of multiple processing systems to perform a trimming cycle can be advantageous when the trimming process includes corrosive gaseous reactants that are difficult to evacuate from a processing system following a gas exposure. A high background pressure containing corrosive gaseous reactants, can result in continued reaction with the gate electrode layer and can erode the semiconductor substrate.

In one embodiment of the invention, the processing system 830 can be used as an analysis chamber for determining a dimension of a gate electrode structure. Based on the measured dimension, a decision can be made to perform another trimming cycle, using the same or another trimming recipe, or to stop the trimming process. The processing system 830 can, for example, be an Optical Digital Profilometer (ODP™) from TIMBRE Technologies, Santa Clara, Calif., or a scanning electron microscope (SEM).

The processing tool 800 can be controlled by a controller 880. The controller 880 can be coupled to and exchange information with substrate loading chambers 810 and 820, processing systems 830-860, and robotic transfer system 870. For example, a program stored in the memory of the controller 880 can be utilized to control the aforementioned components of the processing 800 according to a desired process, and to perform any functions associated with monitoring the process. The controller 880 can furthermore store a process model for creating a set of process parameters for performing a trimming process in the processing tool 800. One example of controller 880 is a DELL PRECISION WORKSTATION 610™, available from Dell Corporation, Austin, Tex. Alternately, the processing tool 800 may contain more than one controller to perform the functions described above.

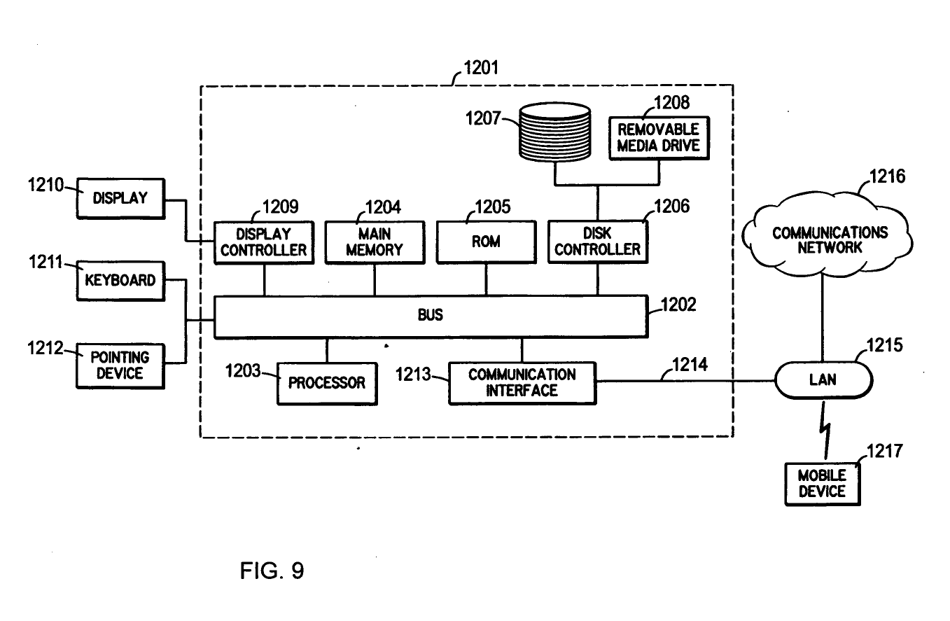

FIG. 9 illustrates a computer system 1201 upon which an embodiment of the present invention may be implemented. The computer system 1201 may be used as the controller of FIG. 8, or a similar controller that may be used to perform any or all of the functions described above. The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), and synchronous DRAM (SDRAM)), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable ROM (PROM), erasable PROM (EPROM), and electrically erasable PROM (EEPROM)) coupled to the bus 1202 for storing static information and instructions for the processor 1203.

The computer system 1201 also includes a disk controller 1206 coupled to the bus 1202 to control one or more storage devices for storing information and instructions, such as a magnetic hard disk 1207, and a removable media drive 1208 (e.g., floppy disk drive, read-only compact disc drive, read/write compact disc drive, compact disc jukebox, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)). The computer system may also include one or more digital signal processors (DSPs) such as the TMS320 series of chips from Texas Instruments, the DSP56000, DSP56100, DSP56300, DSP56600, and DSP96000 series of chips from Motorola, the DSP1600 and DSP3200 series from Lucent Technologies or the ADSP2100 and ADSP21000 series from Analog Devices. Other processors especially designed to process analog signals that have been converted to the digital domain may also be used. The computer system may also include one or more digital signal processors (DSPs) such as the TMS320 series of chips from Texas Instruments, the DSP56000, DSP56100, DSP56300, DSP56600, and DSP96000 series of chips from Motorola, the DSP1600 and DSP3200 series from Lucent Technologies or the ADSP2100 and ADSP21000 series from Analog Devices. Other processors specially designed to process analog signals that have been converted to the digital domain may also be used.

The computer system 1201 may also include a display controller 1209 coupled to the bus 1202 to control a display 1210, such as a cathode ray tube (CRT), for displaying information to a computer user. The computer system includes input devices, such as a keyboard 1211 and a pointing device 1212, for interacting with a computer user and providing information to the processor 1203. The pointing device 1212, for example, may be a mouse, a trackball, or a pointing stick for communicating direction information and command selections to the processor 1203 and for controlling cursor movement on the display 1210. In addition, a printer may provide printed listings of data stored and/or generated by the computer system 1201.

The computer system 1201 performs a portion or all of the processing steps of the invention in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the computer system 1201, for driving a device or devices for implementing the invention, and for enabling the computer system 1201 to interact with a human user (e.g., print production personnel). Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor 1203 for execution. A computer readable medium may take many forms, including but not limited to, non-volatile media, volatile media, and transmission media. Non-volatile media includes, for example, optical, magnetic disks, and magneto-optical disks, such as the hard disk 1207 or the removable media drive 1208. Volatile media includes dynamic memory, such as the main memory 1204. Transmission media includes coaxial cables, copper wire and fiber optics, including the wires that make up the bus 1202. Transmission media also may also take the form of acoustic or light waves, such as those generated during radio wave and infrared data communications.

Various forms of computer readable media may be involved in carrying out one or more sequences of one or more instructions to processor 1203 for execution. For example, the instructions may initially be carried on a magnetic disk of a remote computer. The remote computer can load the instructions for implementing all or a portion of the present invention remotely into a dynamic memory and send the instructions over a telephone line using a modem. A modem local to the computer system 1201 may receive the data on the telephone line and use an infrared transmitter to convert the data to an infrared signal. An infrared detector coupled to the bus 1202 can receive the data carried in the infrared signal and place the data on the bus 1202. The bus 1202 carries the data to the main memory 1204, from which the processor 1203 retrieves and executes the instructions. The instructions received by the main memory 1204 may optionally be stored on storage device 1207 or 1208 either before or after execution by processor 1203.

The computer system 1201 also includes a communication interface 1213 coupled to the bus 1202. The communication interface 1213 provides a two-way data communication coupling to a network link 1214 that is connected to, for example, a local area network (LAN) 1215, or to another communications network 1216 such as the Internet. For example, the communication interface 1213 may be a network interface card to attach to any packet switched LAN. As another example, the communication interface 1213 may be an asymmetrical digital subscriber line (ADSL) card, an integrated services digital network (ISDN) card or a modem to provide a data communication connection to a corresponding type of communications line. Wireless links may also be implemented. In any such implementation, the communication interface 1213 sends and receives electrical, electromagnetic or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201 maybe implemented in baseband signals, or carrier wave based signals. The baseband signals convey the digital data as unmodulated electrical pulses that are descriptive of a stream of digital data bits, where the term “bits” is to be construed broadly to mean symbol, where each symbol conveys at least one or more information bits. The digital data may also be used to modulate a carrier wave, such as with amplitude, phase and/or frequency shift keyed signals that are propagated over a conductive media, or transmitted as electromagnetic waves through a propagation medium. Thus, the digital data may be sent as unmodulated baseband data through a “wired” communication channel and/or sent within a predetermined frequency band, different than baseband, by modulating a carrier wave. The computer system 1201 can transmit and receive data, including program code, through the network(s) 1215 and 1216, the network link 1214, and the communication interface 1213. Moreover, the network link 1214 may provide a connection through a LAN 1215 to a mobile device 1217 such as a personal digital assistant (PDA) laptop computer, or cellular telephone.

The computer system 1201 may be configured to perform the method of the present invention to fabricate semiconductor device by performing a trimming process on a gate electrode structure. In accordance with the present invention, the computer system 1201 may be configured to create a set of process parameters utilizing a process model and controlling the trimming process.

It should be understood that various modifications and variations of the present invention may be employed in practicing the invention. It is therefore to be understood that, within the scope of the appended claims, the invention may be practiced otherwise than as specifically described herein.

1. A method of fabricating a semiconductor device, the method comprising:
determining a first dimension of a gate electrode structure;
choosing a target trimmed dimension;
feeding forward the first dimension and the target trimmed dimension to a process model to create a set of process parameters; and
performing a trimming process on the gate electrode structure, including:
controlling the set of process parameters in the trimming process, and trimming the gate electrode structure.

2. The method according to claim 1, further comprising measuring a trimmed dimension of the trimmed gate electrode structure.

3. The method according to claim 2, further comprising repeating the performing at least once until the target trimmed dimension is obtained.

4. The method according to claim 3, wherein the performing further comprises feeding backward the trimmed dimension to the process model to create a new set of process parameters.

5. The method according to claim 1, wherein the creating of the set of process parameters comprises
calculating a reaction layer thickness from the first dimension, the trimmed dimension, the target trimmed dimension or a combination of two or more thereof; and
determining the set of process parameters based on the reaction layer thickness.

6. The method according to claim 5, wherein the determining further comprises selecting at least one process parameter while keeping other process parameters fixed.

7. The method according to claim 1, wherein the set of process parameters comprises process gas pressure, substrate temperature, plasma power, or process time or a combination of two or more thereof.

8. The method according to claim 1, wherein the measuring comprises using a scattering technique, a scanning electron microscope (SEM), or both to determine the first dimension.

9. The method according to claim 1, wherein the trimming comprises
forming a reaction layer through reaction with the gate electrode structure; and
selectively removing the reaction layer from the unreacted portion of the gate electrode structure by chemical etching.

10. The method according to claim 9, wherein the reaction layer is formed in a self-limiting process.

11. The method according to claim 9, wherein the forming comprises exposing the gate electrode structure to a reactant gas in a thermal process, a plasma process or both.

12. The method according to claim 11, wherein the reactant gas comprises an excited oxygen-containing gas.

13. The method according to claim 9, wherein the forming comprises exposing the gate electrode structure to a wet oxidation process.

14. The method according to claim 9, wherein the selectively removing comprises exposing the gate electrode structure to an etch gas.

15. The method according to claim 9, wherein the selectively removing comprises exposing the gate electrode structure to HF_{(aq)}.

16. The method according to claim 9, wherein the selectively removing comprises exposing the gate electrode structure to HF and NH₃ gases and then to a heat treatment.

17. The method according to claim 9, wherein the selectively removing comprises exposing the gate electrode structure to NF₃ and NH₃ gases in a remote plasma and then to a heat treatment.

18. The method according to claim 9, wherein the selectively removing comprises exposing the gate electrode structure to a wet process.

19. The method according to claim 9, wherein the forming and the removing are carried out in a single processing system.

20. The method according to claim 9, wherein the forming and the removing are carried out in multiple processing systems.

21. The method according to claim 9, wherein the first dimension is a lithographic dimension.

22. The method according to claim 9, wherein the forming includes forming an oxide layer on a surface of the gate electrode.

23. The method according to claim 1, wherein the gate electrode structure comprises a gate electrode layer.

24. The method according to claim 23, wherein the gate electrode layer comprises a Si-containing layer, a metal-containing layer, or both.

25. The method according to claim 24, wherein the gate electrode layer includes the Si-containing layer comprising amorphous Si, poly-Si, or SiGe or a combination of two or more thereof.

26. The method according to claim 24, wherein the gate electrode layer includes the metal-containing layer comprising a metal, a metal nitride, a metal oxide or a combination of two or more thereof.

27. The method according to claim 26, wherein metal-containing layer comprises TaN, TiN, TaSiN, Ru, or RuO₂ or a combination of two or more thereof.

28. The method according to claim 23, wherein the gate electrode structure further comprises an ARC layer.

29. The method according to claim 28, wherein the ARC layer comprises an organic ARC layer or an inorganic ARC layer.

30. The method according to claim 28, wherein the ARC layer comprises SiN.

31. The method according to claim 1, further comprising using the trimmed gate electrode structure as a mask layer for anisotropic etching.

32. A computer readable medium containing program instructions for execution on a processor, which when executed by the processor, cause a processing tool to perform the steps of claim 1.

33. A semiconductor device, comprising:
a trimmed gate electrode structure formed by the method of claim 1.

34. A processing tool, comprising:
a substrate loading chamber configured for loading and unloading a substrate with a gate electrode structure having a first dimension;
a transfer system configured for transferring the substrate within the processing tool;
at least one processing system configured for performing a trimming process on the gate electrode structure to form a trimmed dimension;
at least one controller configured for storing a process model capable of creating a set of process parameters from the first dimension and a target trimmed dimension, and controlling the set of process parameters in the trimming process; and
a further processing system for measuring the first dimension, the trimmed dimension of the gate electrode structure or both.

35. The processing tool according to claim 34, wherein the at least one processing system is configured to repeat the performing at least once until the target trimmed dimension is obtained.

36. The processing tool according to claim 35, wherein the further processing system measures the trimmed dimension and feeds the trimmed dimension back to the at least one controller to create a new set of process parameters.

37. The processing tool according to claim 34, wherein the at least one controller:
calculates a reaction layer thickness from at least one of the first dimension, the trimmed dimension, and the target trimmed dimension; and
determines the set of process parameters based on the reaction layer thickness.

38. The processing tool according to claim 37, wherein the at least one controller determines the set of process parameters by selecting at least one process parameter while keeping other process parameters fixed.

39. The processing tool according to claim 34, wherein the set of process parameters comprises process gas pressure, substrate temperature, plasma power, process time or a combination of two or more thereof.

40. The processing tool according to claim 34, wherein the further processing system comprises a scattering technique, a scanning electron microscope (SEM) or both.

41. The processing tool according to claim 34, wherein the at least one processing system:
forms a reaction layer through reaction with the gate electrode structure; and
selectively removes the reaction layer from the unreacted portion of the gate electrode structure by chemical etching.

42. The processing tool according to claim 41, wherein the reaction layer is formed in a self-limiting process.

43. The processing tool according to claim 41, wherein the at least one processing system exposes the gate electrode structure to a reactant gas in a thermal process, a plasma process or both to form the reaction layer.

44. The processing tool according to claim 43, wherein the reactant gas comprises an excited oxygen-containing gas.

45. The processing tool according to claim 41, wherein the at least one processing system exposes the gate electrode structure to a wet oxidation process to form the reaction layer.

46. The processing tool according to claim 41, wherein the at least one processing system exposes the gate electrode structure to an etch gas to remove the reaction layer.

47. The processing tool according to claim 41, wherein the at least one processing system exposes the gate electrode structure to HF_{(aq)} to remove the reaction layer.

48. The processing tool according to claim 41, wherein the at least one processing system exposes the gate electrode structure to HF and NH₃ gases and then to a heat treatment.

49. The processing tool according to claim 41, wherein the at least one processing system exposes the gate electrode structure to NF₃ and NH₃ gases in a remote plasma and then to a heat treatment.

50. The processing tool according to claim 41, wherein the at least one processing system exposes the gate electrode structure to a wet process.

51. The processing tool according to claim 41, wherein the at least one processing system consists of a single processing system.

52. The processing tool according to claim 41, wherein the at least one processing system comprises multiple processing systems.

53. The processing tool according to claim 34, wherein the first dimension is a lithographic dimension.

54. The processing tool according to claim 41, wherein the at least one processing system forms an oxide layer on a surface of the gate electrode as the reaction layer.

55. The processing tool according to claim 34, wherein the gate electrode structure comprises a gate electrode layer.

56. The processing tool according to claim 55, wherein the gate electrode layer comprises a Si-containing layer, a metal-containing layer or both.

57. The processing tool according to claim 56, wherein the gate electrode layer includes the Si-containing layer comprising amorphous Si, poly-Si, or SiGe or a combination of two or more thereof.

58. The processing tool according to claim 56, wherein the gate electrode layer includes the metal-containing layer comprising a metal, a metal nitride, a metal oxide or a combination of two or more thereof.

59. The processing tool according to claim 58, wherein metal-containing layer comprises TaN, TiN, TaSiN, Ru, RuO₂ or a combination of two or more thereof.

60. The processing tool according to claim 55, wherein the gate electrode structure further comprises an ARC layer.

61. The processing tool according to claim 60, wherein the ARC layer comprises an organic ARC layer or an inorganic ARC layer.

62. The processing tool according to claim 60, wherein the ARC layer comprises SiN.

63. The processing tool according to claim 34, wherein the at least one processing system is configured for wet processing.

64. The processing tool according to claim 34, further comprising an additional processing system configured for plasma etching.

65. The processing tool according to claim 64, wherein the additional processing system is configured for RIE.
